(19) United States
(12) Patent Application Publication
(10) Pub. No.: US 2021/0399155 A1
(43) Pub. Date: Dec. 23, 2021

(54) ASYMMETRIC LATERAL AVALANCHE PHOTODETECTOR

(71) Applicant: MCMASTER UNIVERSITY, Hamilton (CA)

(72) Inventors: Andrew Peter KNIGHTS, Dundas (CA); David E. HAGAN, Mississauga (CA)

(21) Appl. No.: 17/350,908

(22) Filed: Jun. 17, 2021

Related U.S. Application Data
(60) Provisional application No. 63/041,266, filed on Jun. 19, 2020.

(51) Int. Cl. H01L 31/107; H01L 31/0232

(52) U.S. Cl. CPC H01L 31/1075; H01L 31/02327

(57) ABSTRACT

Avalanche photodetector devices are disclosed in which spatial asymmetry is employed to preferentially enhance avalanche multiplication of electrons. In some example embodiments, an avalanche photodetector device includes p-doped and n-doped regions and a central waveguide region, where the p-doped region is laterally offset from the central waveguide by a first lateral offset region, and where the n-doped region is laterally offset from the central waveguide by a second lateral offset region. The first and second lateral offset regions are asymmetrically defined such that impact ionization and avalanche multiplication of electrons in the second laterally offset region is enhanced relative to that of holes in the first laterally offset region. In some example implementations, the asymmetry may be provided by a difference in relative heights and/or lateral spatial extends (widths) of the lateral offset regions, such that the electric field, or a spatial extent associated therewith, is enhanced for electrons.

### CROSS-REFERENCE TO RELATED APPLICATION

This application claims priority to U.S. Provisional Patent Application No. 63/041,266, titled “ASYMMETRIC LATERAL AVALANCHE PHOTODETECTOR” and filed on Jun. 19, 2020, the entire contents of which is incorporated herein by reference.

### BACKGROUND

The present disclosure relates to lateral avalanche photodetectors. In some aspects, the present disclosure relates to deep-level doped lateral silicon avalanche photodetectors.

The avalanche photodetector (APD) is a widely deployed semiconductor device used for the detection of optical signals with relatively low power. By application of a large electric field, primary photocarriers in the device can be accelerated such that they create additional carriers in an “avalanche” effect. The most commonly used material for the fabrication of APDs is silicon.

### SUMMARY

Avalanche photodetector devices are disclosed in which spatial asymmetry is employed to preferentially enhance avalanche multiplication of electrons. In some example embodiments, an avalanche photodetector device includes p-doped and n-doped regions and a central waveguide region, where the p-doped region is laterally offset from the central waveguide by a first lateral offset region, and where the n-doped region is laterally offset from the central waveguide by a second lateral offset region. The first and second lateral offset regions are asymmetrically defined such that impact ionization and avalanche multiplication of electrons in the second laterally offset region is enhanced relative to that of holes in the first laterally offset region. In some example implementations, the asymmetry may be provided by a difference in relative heights and/or lateral spatial extends (widths) of the lateral offset regions, such that the electric field, or a spatial extent associated therewith, is enhanced for electrons.

Accordingly, in one aspect, there is provided an asymmetric waveguide avalanche photodiode device comprising:
a substrate; and
a silicon device layer residing on the substrate, the silicon device layer comprising:
   a silicon waveguide comprising deep levels;
   an n-type region residing on a first side of the silicon waveguide;
   a first silicon lateral offset region laterally extending between the silicon waveguide and the n-type region;
   a p-type region residing on a second side of the silicon waveguide; and
   a second silicon lateral offset region laterally extending between the silicon waveguide and the p-type region;
wherein a height of the second silicon lateral offset region exceeds a height of the first silicon lateral offset region, thereby establishing a spatial asymmetry that enhances avalanche multiplication, within the first silicon lateral offset region, of electrons photogenerated by absorption of sub-bandgap light by the deep levels, relative to avalanche multiplication of photogenerated holes, when a reverse bias, sufficient for generating impact ionization within the first silicon lateral offset region, is applied between the p-type region and the n-type region.

In some implementations of the device, a lateral extent of the first silicon lateral offset region, along a direction perpendicular to a longitudinal axis of the silicon waveguide, exceeds a lateral extent of the second silicon lateral offset region.

In some implementations of the device, the height of the second silicon lateral offset region is less than 0.99 times a height of the silicon waveguide.

In some implementations of the device, the height of the first silicon lateral offset region is greater than 0.01 times a height of the silicon waveguide.

In some implementations of the device, the second silicon lateral offset region has a lateral extent of at least 100 nm.

In some implementations of the device, the second silicon lateral offset region has a lateral extent such that parasitic absorption of light guided by the silicon waveguide and having a wavelength of 1500 nm is less than 10%.

In some implementations of the device, a concentration of deep levels in the silicon waveguide is at least 10¹⁴ cm⁻³.

In some implementations of the device, the first silicon lateral offset region comprises deep levels.

In some implementations of the device, a concentration of deep levels in the first silicon lateral offset region is greater than a concentration of deep levels in the second silicon lateral offset region.

In some implementations of the device, a concentration of shallow dopants in the silicon waveguide is less than 10¹⁹ cm⁻³.

In another aspect, there is provided an asymmetric avalanche photodiode device comprising:
a substrate; and
a semiconductor device layer residing on the substrate, the semiconductor device layer comprising:
   an elongate semiconductor region suitable for absorbing incident light and responsively generating photocarriers;
   an n-type region residing on a first side of the elongate semiconductor region;
   a first semiconductor lateral offset region laterally extending, in a direction perpendicular to a longitudinal axis of the elongate semiconductor region, between the elongate semiconductor region and the n-type region;
   a p-type region residing on a second side of the elongate semiconductor region; and
   a second semiconductor lateral offset region laterally
extending between the elongate semiconductor region and the p-type region;

wherein a height of the second semiconductor lateral offset region exceeds a height of the first semiconductor lateral offset region, thereby establishing a spatial asymmetry that enhances avalanche multiplication, within the first semiconductor lateral offset region, of electrons photogenerated by absorption of light within the elongate semiconductor region, relative to avalanche multiplication of photogenerated holes, when a reverse bias, sufficient for generating impact ionization within the first semiconductor lateral offset region, is applied between the p-type region and the n-type region.

In another aspect, there is provided an asymmetric waveguide avalanche photodiode device comprising:
a substrate; and
a silicon device layer residing on the substrate, the silicon device layer comprising:
   a silicon waveguide comprising deep levels;
   an n-type region residing on a first side of the silicon waveguide;
   a first silicon lateral offset region laterally extending between the silicon waveguide and the n-type region;
   a p-type region residing on a second side of the silicon waveguide; and
the first silicon lateral offset region having a lateral extent, along a direction perpendicular to a longitudinal axis of the silicon waveguide, such that the n-type region resides further from the silicon waveguide than the p-type region, thereby establishing a spatial asymmetry that enhances avalanche multiplication, within the first silicon lateral offset region, of electrons photogenerated by absorption of sub-bandgap light by the deep levels, relative to avalanche multiplication of photogenerated holes, when a reverse bias, sufficient for generating impact ionization within the first silicon lateral offset region, is applied between the p-type region and the n-type region.

In some implementations of the device, the p-type region is laterally offset from the silicon waveguide by a second silicon lateral offset region, and wherein the lateral extent of the first silicon lateral offset region exceeds a lateral extent of the second silicon lateral offset region. The first silicon lateral offset region may be absent of a p-doped subregion. A maximum electric field within the second silicon lateral offset region may exceed a maximum electric field within the first silicon lateral offset region under application of the reverse bias.

In some implementations of the device, a concentration of deep levels in the silicon waveguide is at least 10¹⁴ cm⁻³.

In some implementations of the device, the first silicon lateral offset region comprises deep levels.

In some implementations of the device, a concentration of shallow dopants in the silicon waveguide is less than 10¹⁹ cm⁻³.

In another aspect, there is provided an asymmetric avalanche photodiode device comprising:
a substrate; and
a semiconductor device layer residing on the substrate, the semiconductor device layer comprising:
   an elongate semiconductor region suitable for absorbing incident light and responsively generating photocarriers;
   an n-type region residing on a first side of the elongate semiconductor region;
   a first semiconductor lateral offset region laterally extending between the elongate semiconductor region and the n-type region;
   a p-type region residing on a second side of the elongate semiconductor region; and
   a second semiconductor lateral offset region laterally extending between the elongate semiconductor region and the p-type region;
the first semiconductor lateral offset region having a lateral extent, along a direction perpendicular to a longitudinal axis of the elongate semiconductor region, such that the n-type region resides further from elongate semiconductor region than the p-type region, thereby establishing a spatial asymmetry that enhances avalanche multiplication, within the first semiconductor lateral offset region, of electrons photogenerated by absorption of light within the elongate semiconductor region, relative to avalanche multiplication of photogenerated holes, when a reverse bias, sufficient for generating impact ionization within the first semiconductor lateral offset region, is applied between the p-type region and the n-type region.

A further understanding of the functional and advantageous aspects of the disclosure can be realized by reference to the following detailed description and drawings.

### BRIEF DESCRIPTION OF THE DRAWINGS

Embodiments will now be described, by way of example only, with reference to the drawings, in which:

FIG. 1A shows a cross-sectional view of a symmetric avalanche photodetector device.

FIG. 1B shows various spatial measures within a cross-section taken through the symmetric avalanche photodetector device.

FIG. 1C plots the electric field within a cross-section taken through the symmetric avalanche photodetector device when the device is reverse biased.

FIG. 2A shows a cross-sectional view of an asymmetric avalanche photodetector device having a height asymmetry on either side of the central waveguide region.

FIG. 2B shows various spatial measures within a cross-section taken through the asymmetric avalanche photodetector device having a height asymmetry on either side of the central waveguide region.

FIG. 2C plots the electric field within a cross-section taken through the asymmetric avalanche photodetector device having a height asymmetry on either side of the central waveguide region when the device is reverse biased.

FIG. 3A shows a cross-sectional view of an asymmetric avalanche photodetector device having a lateral asymmetry of the n+ and p+ regions relative to the central waveguide region.

FIG. 3B shows various spatial measures within a cross-section taken through the asymmetric avalanche photodetector device having a lateral asymmetry of the n+ and p+ regions relative to the central waveguide region.

FIG. 3C plots the electric field within a cross-section taken through the asymmetric avalanche photodetector device having a lateral asymmetry of the n+ and p+ regions relative to the central waveguide region when the device is reverse biased.

FIG. 4 plots the electric field along the lateral dashed paths shown in FIGS. 1C, 2C and 3C.

FIG. 5 plots the impact generation rate along the lateral dashed paths shown in FIGS. 1C, 2C and 3C.

FIG. 6 plots the electron ionization coefficient along the lateral dashed paths shown in FIGS. 1C, 2C and 3C.

### DETAILED DESCRIPTION

Various embodiments and aspects of the disclosure will be described with reference to details discussed below. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosure.

As used herein, the terms “comprises” and “comprising” are to be construed as being inclusive and open ended, and not exclusive. Specifically, when used in the specification and claims, the terms “comprises” and “comprising” and variations thereof mean the specified features, steps or components are included. These terms are not to be interpreted to exclude the presence of other features, steps or components.

As used herein, the term “exemplary” means “serving as an example, instance, or illustration,” and should not be construed as preferred or advantageous over other configurations disclosed herein.

As used herein, the terms “about” and “approximately” are meant to cover variations that may exist in the upper and lower limits of the ranges of values, such as variations in properties, parameters, and dimensions. Unless otherwise specified, the terms “about” and “approximately” mean plus or minus 25 percent or less.

It is to be understood that unless otherwise specified, any specified range or group is as a shorthand way of referring to each and every member of a range or group individually, as well as each and every possible sub-range or sub-group encompassed therein and similarly with respect to any sub-ranges or sub-groups therein. Unless otherwise specified, the present disclosure relates to and explicitly incorporates each and every specific member and combination of sub-ranges or sub-groups.

As used herein, the term “on the order of”, when used in conjunction with a quantity or parameter, refers to a range spanning approximately one tenth to ten times the stated quantity or parameter.

Unless defined otherwise, all technical and scientific terms used herein are intended to have the same meaning as commonly understood to one of ordinary skill in the art. Unless otherwise indicated, such as through context, as used herein, the following terms are intended to have the following meanings:

As used herein, the phrase “deep level” pertains to the energy level of a dopant or defect for which the energy level separation relative to a band edge is at least 3 times kT, where k is Boltzman's constant and T is temperature.

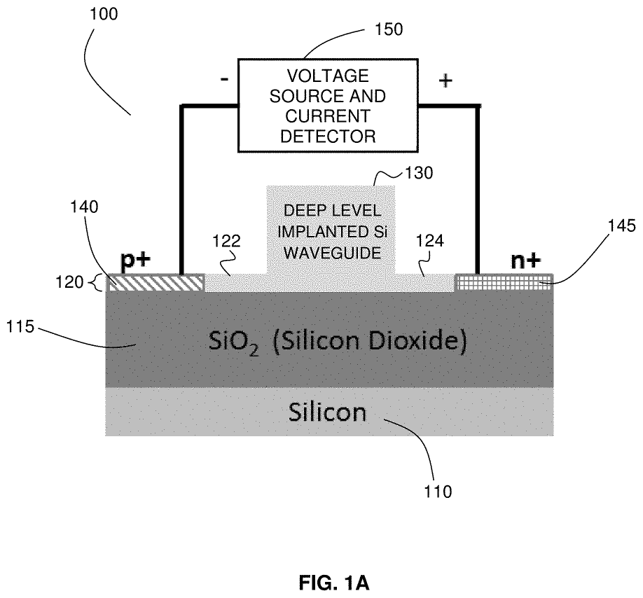

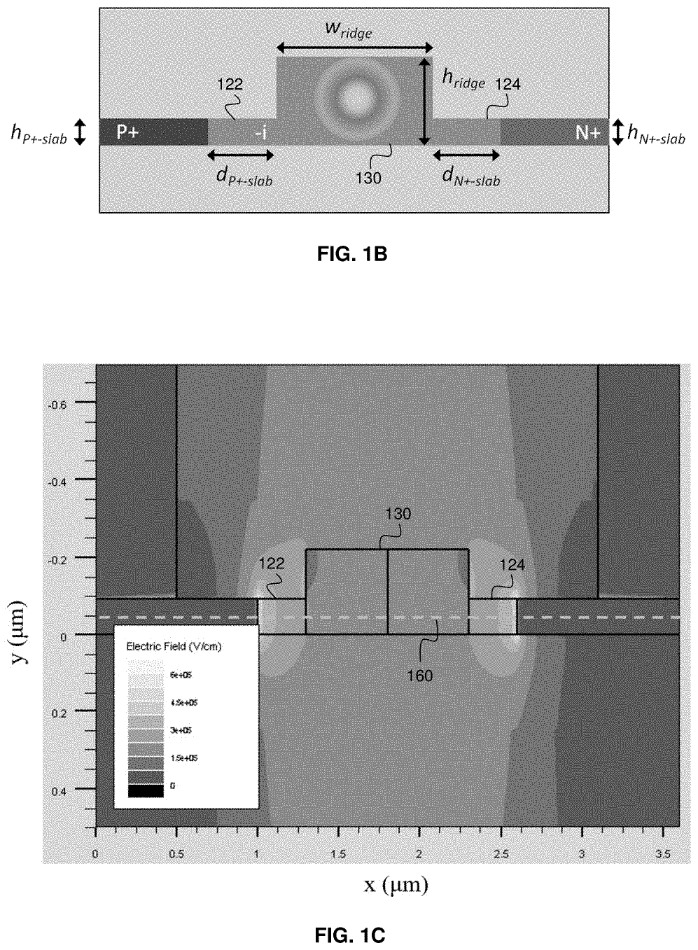

While silicon APDs are known for use in above-bandgap operation, the implantation of silicon with deep levels permits absorption of sub-bandgap light, facilitating the functioning of a deep-level-implanted silicon material as a photodetector. For example, Ackert et al. (Ackert et al., Opt. Express 21, 19530-1957, 2013) has described a deep-level-implanted waveguide silicon avalanche photodiode, which is schematically illustrated in FIG. 1A.

The Ackert device 100 employs a silicon-on-insulator structure, as shown in the figure, in which a silicon substrate 110 supports a SiO₂ insulator layer 115, upon which a top silicon device layer 120 is provided. The central silicon waveguide 130 region is formed on the silicon device layer 120. The silicon waveguide 130 is doped with deep level impurities (e.g. substitutional impurities or lattice defects) that facilitates the excitation of photocarriers via the absorption of sub-bandgap light.

As shown in the figure, p+ and n+ regions 140 and 145 are respectively provided on opposites sides of waveguide 130, in a manner suitable for applying an electric field within waveguide 130. The adjacent p+ and n+ regions 140 and 145, and silicon waveguide 130, together form a p-i-n junction (the “intrinsic” region being doped/implanted with deep level impurities). Metal electrodes (not shown) may be respectively formed over (or otherwise be brought into electrical communication with) the p+ and n+ regions 140 and 145, and the electrodes may be contacted, for example via bonded wires, to electrical circuitry 150 that includes, for example, a voltage source for generating a reverse bias (potential difference) and a current detector (e.g. amplifier circuit). The applied reverse bias applied to the Ackert device 100 is sufficient to support impact ionization of both electrons and holes.

FIG. 1B shows a cross-sectional view of the silicon device layer and the optical mode that is axially guided within the waveguide. Photons are absorbed within the low-doped or intrinsic region and electron-hole pairs are created commensurate with the waveguide mode (approximated by the circular region).

As can be seen in FIGS. 1A and 1B, the Ackert device includes intrinsic offset regions 122 and 124 that laterally offset the respective p+ and n+ regions 124 and 124 from the central waveguide region 130. These lateral offset regions facilitate the generation of secondary carriers (avalanche multiplication) via impact ionization.

FIG. 1C plots the electric field within a cross-sectional region of a device having a 90 nm P-type slab height, a 90 nm N-type slab height, a 1 μm ridge width, and a 220 nm ridge height. The electric field extends within the lateral offset regions 122 and 124 when the device is reverse biased, such that photo-generated carriers drift toward the p+ and n+ regions 122 and 124. Under sufficiently strong electric fields, avalanche carrier generation takes place, significantly increasing the photocurrent. Both holes and electrons are generated and both are subjected to the avalanche process, creating additional carriers at a rate related to their ionization coefficients. It is noted that in silicon, the ionization coefficient of electrons is larger than holes, while these coefficients increase with electric field and become less dissimilar as the electric field increases.

As can be clearly seen in FIGS. 1A-1C, the Ackert device is spatially symmetric relative to the central waveguide region. As a consequence, the primary carrier injection into the higher field lateral offset regions of the APD takes place via both electrons and holes, which are subjected to essentially the same electric field strength. The present inventors realized that such a configuration is not ideal from the viewpoint of excess noise generation and device bandwidth, understanding that in order to achieve improved noise performance, the ionization coefficients of the primary carriers should be as different as possible and the avalanche process should be predominantly initiated by the carrier species with the higher ionization rate. The present inventors thus realized improved silicon-based APD devices could be achieved by employing a design that promotes impact ionization via electrons rather than holes via an asymmetric spatial configuration.

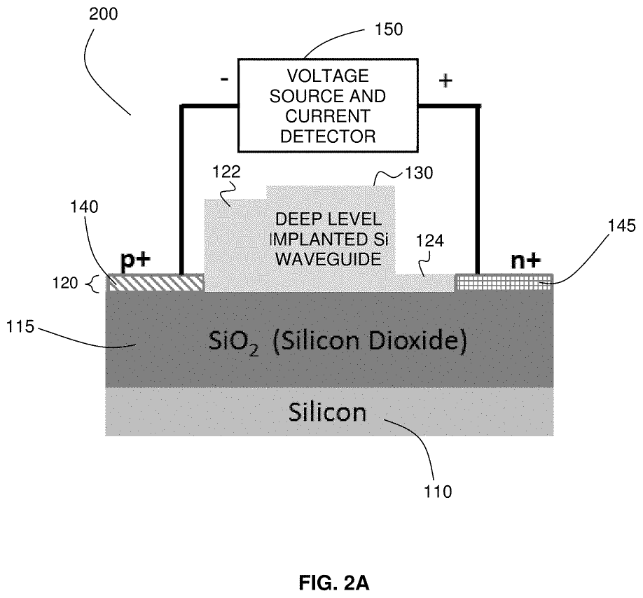

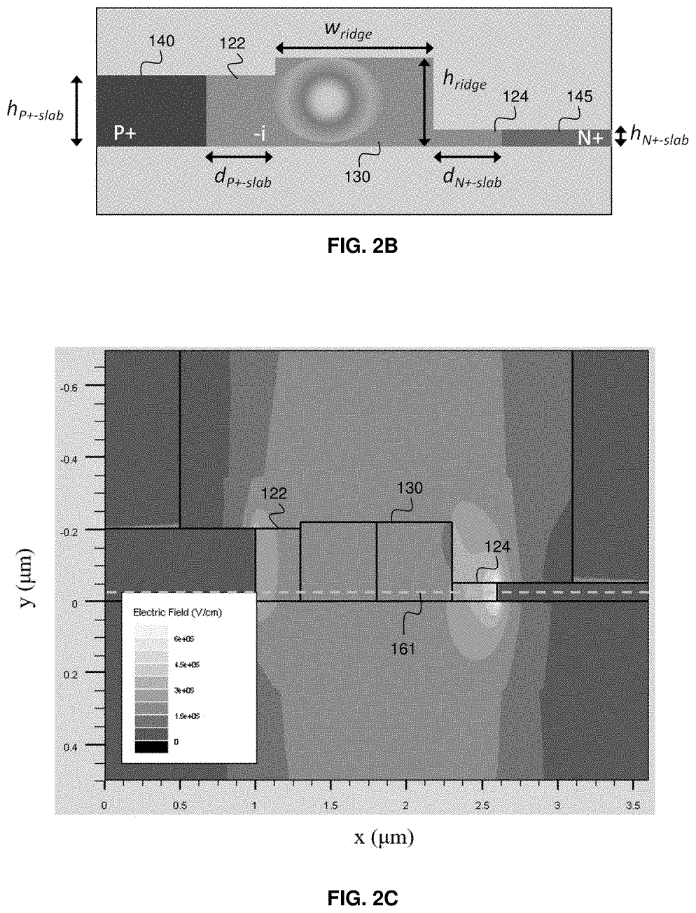

An example embodiment of a spatially asymmetric deep-level implanted silicon waveguide APD is shown in FIGS. 2A-2C. As shown in the figures, spatial asymmetry is achieved by increasing the height (thickness) of the lateral offset region 122 on the p+ side of the waveguide region 130, which reduces the electric field on the p+ side of the waveguide region 130 and enhances the electric field within the lateral offset region 124 on the n+ side of the device. The reduction of the electric field within the p+ side lateral offset region 122 reduces or suppress impact ionization via injected holes, while the increase in the electric field within the lateral offset region 124 on the n+ side of the device enhances impact ionization (and secondary carrier generation) via the injected electrons. Accordingly, such a device configuration leads to improved noise performance relative to its symmetric counterpart of FIGS. 1A-1C.

The reverse bias may be applied such that a threshold of avalanche multiplication is achieved for electrons without achieving a threshold of avalanche multiplication for holes. The skilled artisan may experiment with different height ranges of the p+ side and n+ side lateral offset regions 122 and 124, for a given reverse bias and waveguide configuration, in order to identify suitable respective heights that result in preferential avalanche multiplication of electrons. The present inventors have found, for example, that a suitable reverse bias is one that results in an electric field within a range of 1×10⁵ to 1×10⁶ V/cm within the n+ side lateral offset region, when the APD is fabricated using silicon.

As shown in FIG. 2B, the spatial asymmetry that leads to preferential electron impact ionization and avalanche multiplication is achieved via the differences in heights of the h_{P+slab}>h_{N+slab}. It will be understood that the larger the ratio of h_{P+slab}/h_{N+slab}, the greater the asymmetry in field strength in the two slabs will be. As h_{N+slab} decreases, the risk of damage to the material from excessive current density may increase.

As h_{P+slab} becomes close in height to h_{ridge}, the center of the optical mode will tend to extend toward the p+ side, as illustrated in FIG. 2B. As a consequence, the photogenerated carriers are created toward the p+ side, introducing further asymmetry. This modal asymmetry provides a second mechanism that favours enhanced avalanche multiplication of photogenerated electrons by providing an increased distance over which electrons travel toward the n+ region, compared to the distance traveled by holes to the p+ region, thus promoting a higher probability for impact ionization of electrons to occur.

In some example implementations, the height asymmetry of the lateral offset regions 122 and 124 may be provided such that h_{P+slab} is no greater than 0.99*h_{ridge} and h_{N+slab} is greater than 0.01*h_{ridge}. The width of the central region, w_{ridge} should be sufficiently large to confine the optical mode horizontally, while being sufficiently small enough to promote high enough electric fields at reasonable voltages. In some example implementations, the central waveguide region may be defined such that 10*λ>h_{ridge}>0.025*λ and 10*λ>w_{ridge}>0.025*λ, where λ is an operating wavelength of the device.

The lateral spatial extent of the p+ side lateral offset region 122 may be selected such that a suitable reduction in the electric field within the p+ side lateral offset region 122 prevents an onset of avalanche multiplication of holes, while facilitating the avalanche multiplication of electrons, within the n+ side lateral offset region 124, for a given applied reverse bias or reverse bias range. In some example implementations, the spatial extent of the lateral offset region 122 may be between 50 and 100 nm, between 50 and 200 nm, or between 100 and 200 nm. In some example implementations, the lateral extent of the p+ side lateral offset region may be sufficiently small such that parasitic absorption of light guided by said silicon waveguide and having a wavelength of 1500 nm is less than 10%.

FIG. 2C plots the electric field within a cross-section taken through an asymmetric avalanche photodetector having a height asymmetry of the lateral offset regions 122 and 124 under reverse bias. The device was modeled with a 200 nm P-type slab height, a 50 nm N-type slab height, a 1 μm ridge width, and 220 nm ridge height. As can be seen by comparison with FIG. 1C, the increased height of the lateral offset region 122 on the p+ side leads to a reduction of the electric field within this region, while the decreased height of the lateral offset region on the n+ side leads to an increased electric field, thereby promoting increased impact ionization and avalanche multiplication of electrons relative to holes.

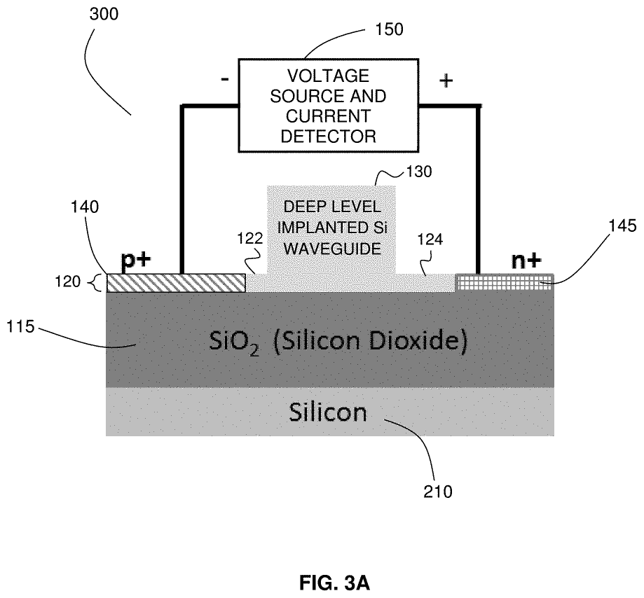

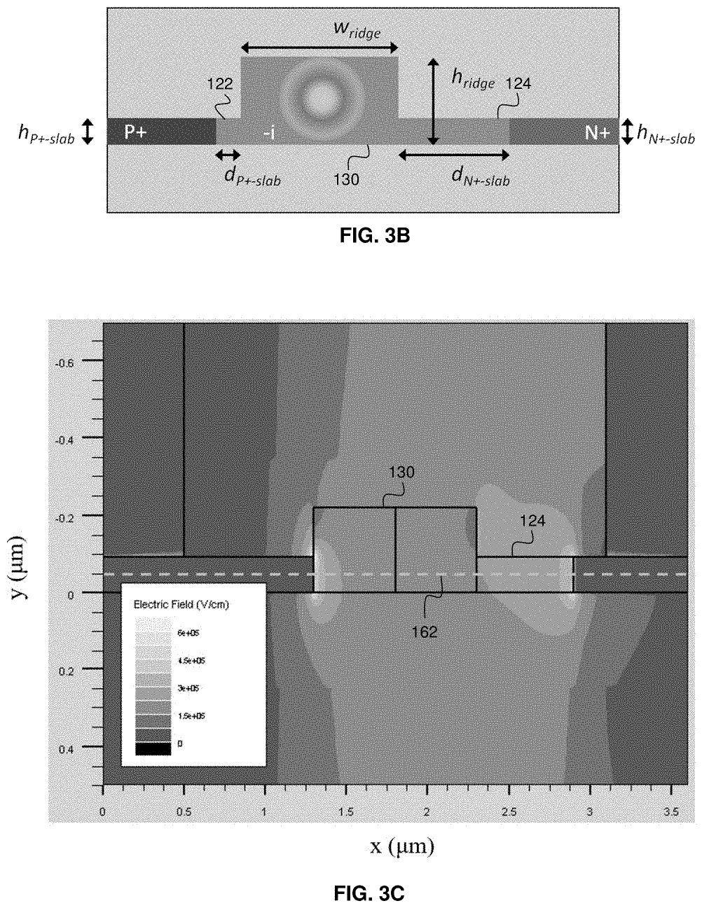

Another example embodiment that employs spatial asymmetry is illustrated in FIGS. 3A-3C, in which the spatial asymmetry that confers enhanced impact ionization and avalanche multiplication of electrons is provided in the lateral direction. As shown in the figures, p+ side lateral offset region 122 is less than the n+ side lateral offset region 124, such that d_{P+slab}<d_{N+slab}, and such that the n+ region 145 is further from the central waveguide region 130 than the p+ region 140. Accordingly, photogenerated electrons will encounter the electric field over a longer distance than the photogenerated holes under reverse bias, promoting a higher probability for impact ionization of electrons to occur relative to holes.

The reverse bias may be applied such that a threshold of avalanche multiplication is achieved for electrons without achieving a threshold of avalanche multiplication is achieved for holes. The skilled artisan may experiment with different lateral extent ranges of the p+ side and n+ side lateral offset regions 122 and 124, for a given reverse bias and waveguide configuration, in order to identify suitable respective lateral extents that result in preferential avalanche multiplication of electrons.

In some example embodiments, the p+ side lateral offset region 122 may be less than 100 nm, less than 50 nm, less than 20 nm, or zero. The choice of a suitable lateral extent of the p+ side lateral offset region 122 may depend on the modal confinement of the optical mode within the central waveguide region, with the lateral extent of the p+ side lateral offset region being selected to avoid or reduce parasitic absorption of the guided optical mode. Fore example, in large cross-section waveguides, it may be possible for the p+ region 140 to be very close to the central waveguide region 130 without leading to significant parasitic absorption. For example, this may be the case when h_{N+slab} and h_{P+slab} are approximately less than half of h_{ridge}.

In some example implementations, the lateral extent of the n+ side lateral offset region 124 is 1.1 times to 10 times longer than the lateral extent of the p+ side lateral offset region 122. In some example implementations, the n+ offset region 124 is larger than the p+ offset region 22 by at least 100 nm while maintaining a lateral spatial extent that is sufficiently small to maintain an electric field above an avalanche threshold (e.g. ˜10⁵ V/cm) for a given reverse bias voltage, such as maximum lateral spatial extend of 1000 nm.

FIG. 3C plots the electric field within a cross-section taken through an asymmetric avalanche photodetector having a height asymmetry of the lateral offset regions 122 and 124 under reverse bias. The device was modeled with a 90 nm P-type slab height, 90 nm N-type slab height, 1 μm ridge width, 220 nm ridge height. As can be seen by comparison with FIG. 1C, the increased length of the lateral offset region 124 on the n+ side leads to an increased interaction length of the injected electrons with the electric field relative to the p+ lateral offset region 122, thereby promoting increased impact ionization and avalanche multiplication of electrons relative to holes.

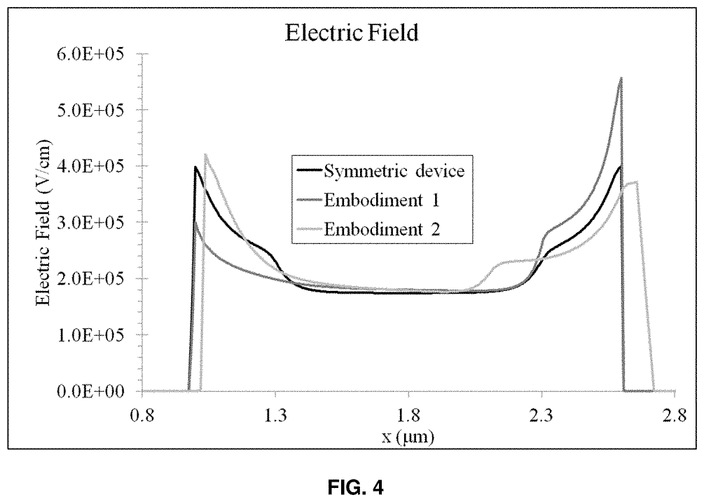

Referring now to FIG. 4, the electric field is plotted along the contours 160, 161 and 162 in FIGS. 2C, 3C and 4C, respectively, for the cases of a symmetric device, a device with height asymmetry in the lateral offset regions, and a device with asymmetry in the lateral extent of the lateral offset regions. The symmetric device shows a symmetric electric field profile with higher field concentrations toward the edges of the P+ and N+ contacts due to the larger potential across the thinner slab regions. However, the asymmetric device with an asymmetry in the relative heights of the lateral offset regions 122 and 124 shows increased electric field toward the N+ region and reduced electric field toward the P+ region due to the difference in potentials across the respectively thinner and thicker slab regions. The asymmetric device with an asymmetry in the relative lateral extents of the lateral offset regions 122 and 124 shows an extension of a high electric field on the N+ side (relative to the P+ side) due to the wider slab region (w_{N+slab}). As can be seen in the figure, even though the electric field amplitude is higher on the p+ side of the device for the case of an asymmetric device with an asymmetry in the relative lateral extent of the lateral offset regions 122 and 124, the electric field within the extended n+ lateral offset region 124 has an increased value, relative to the central waveguide region, over a much longer lateral extent than the corresponding p+ lateral offset region 122, thereby supporting the preferential avalanche multiplication of injected electrons.

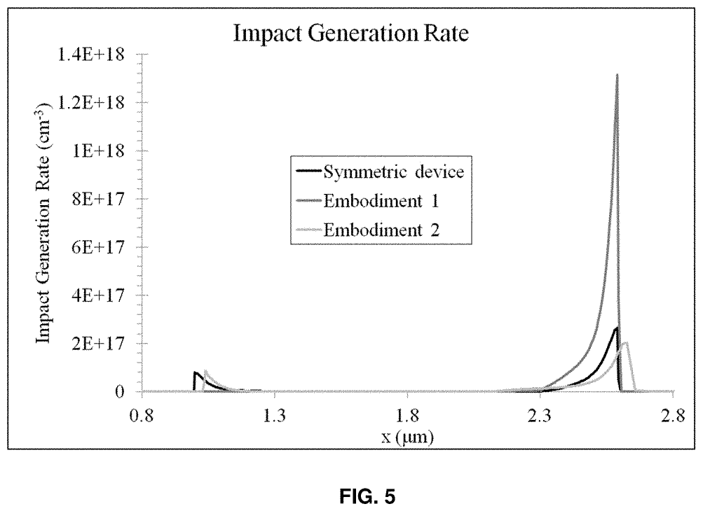

FIG. 5 plots the impact ionization rate along the contours 160, 161 and 162 in FIGS. 2C, 3C and 4C, respectively, for the cases of a symmetric device, a device with height asymmetry in the lateral offset regions, and a device with asymmetry in the lateral extents of the lateral offset regions. The symmetric device shows an asymmetric impact generation rate toward the N+ contacts due to the naturally higher electron ionization coefficient as compared with the hole ionization coefficient. The impact generation rate is strongly correlated with the electric field strength. However, the asymmetric device with an asymmetry in the relative heights of the lateral offset regions 122 and 124 shows an enhanced impact generation rate toward the N+ region due to the higher electric field toward the N+ side as described previously. The reduced electric field toward the P+ region conversely decreases the impact generation rate in this region. The asymmetric device with an asymmetry in the relative lateral extents of the lateral offset regions 122 and 124 shows an elongated region of high impact generation rate due to the wider slab region toward the N+ region.

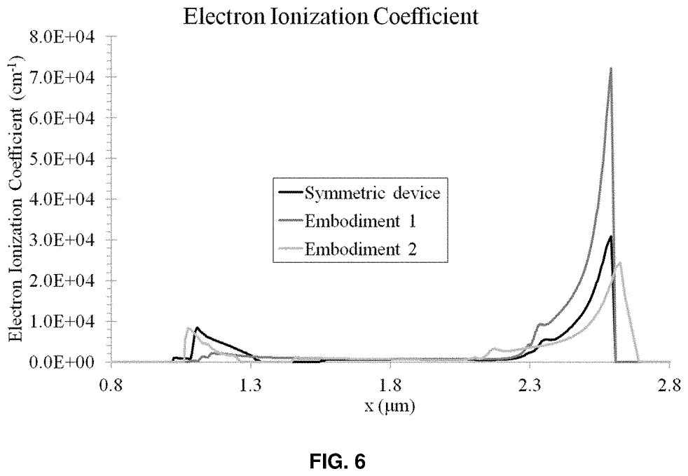

FIG. 6 plots the electron ionization coefficient along the contours 160, 161 and 162 in FIGS. 2C, 3C and 4C, respectively, for the cases of a symmetric device, a device with height asymmetry in the lateral offset regions, and a device with asymmetry in the lateral extents of the lateral offset regions. The symmetric device shows a higher electron ionization coefficient toward the N+ side relative to the P+ side due to the drift of electrons toward the N+ region. The reduced ionization coefficients toward the P+ side demonstrate that electrons are being generated here from impact ionization but do not avalanche strongly in this region as they drift toward the N+ region, passing through the intrinsic region where the field is lower. However, the asymmetric device with an asymmetry in the relative heights of the lateral offset regions 122 and 124 shows a strongly increased electron ionization coefficient in the N+ region corresponding to the higher electric field. As mentioned previously these coefficients are field-dependent. The asymmetric device with an asymmetry in the relative lateral extents of the lateral offset regions 122 and 124 shows an elongated region of high electron ionization coefficient corresponding to the longer slab region.

Deep levels may be generated within the silicon waveguide by ion implantation, which is a common fabrication process in the semiconductor industry. Chemically inert ions (such as hydrogen, helium, nitrogen, argon, silicon, germanium); or ions that could be chemically active if subjected to a post ion implantation high temperature anneal in excess of 800K (such as boron, phosphorus, arsenic) may be accelerated, for example, to an energy of between 1 and 4000 keV, and penetrate the silicon, creating lattice defects (which are electrical deep-levels typically greater than 3 times kT in energy from either the conduction or valence band, where K is Boltzmann's constant and T is temperature) through collisions with lattice atoms. The number of deep levels and their position depends on the energy, dose and mass of the accelerated ions. In some example implementations, ion implantation may be followed by a low-temperature (e.g. up to 600K) thermal treatment which may increase the sensitivity of the waveguide to sub-bandgap photons. Deep levels may also be introduced via low-temperature (less than 600K) deposition of material which may form the waveguide. Deep levels may also be introduced by subjecting the waveguide to an inert plasma process. In some example implementations, the concentration of deep levels within the central waveguide region may be between 1×10¹⁴ cm⁻³ and 1×10¹⁹ cm⁻³.

Although the preceding example embodiments describe the central waveguide region as including deep levels to facilitate absorption of sub-bandgap light, it will be understood that at least the n+ side lateral offset region 110 may also be doped to include deep levels. The presence of deep levels in the n+ lateral offset region may provide an increased probability (cross-section) for electron impact ionization, further enhancing electron avalanche multiplication relative to hole avalanche multiplication. According to some example methods, deep levels may be generated within n+ lateral offset region for which ionization is preferentially initiated by electrons. Examples of such deep levels include the divacancy, vacancy-impurity complexes (such as oxygen-vacancy, carbon-vacancy, boron-vacancy, phosphorus-vacancy), interstitial clusters of between 1 and several million atoms, dislocations, clusters of vacancies between 2 and several million vacancies.

In some example implementations, apart from the presence of deep levels, the lateral offset regions and central waveguide regions may be otherwise intrinsic (absent of shallow dopants) or include shallow dopants at concentrations less than 1×10¹⁹cm⁻³. In other example implementations, a portion of the lateral offset region 122 that is closer to the central waveguide region than the n+ region may be doped with a concentration of p-type dopants having a concentration that is less that a concentration of p-type dopants within the p+ region. This p region effectively reduces the potential drop of the reverse bias over the p+ side lateral offset region 124 and the central waveguide region while increasing the electric field within the remaining portion of the n+ side lateral offset region, thereby preferentially enhancing electron avalanche multiplication.

The preceding example embodiments have separately illustrated the use of unidirectional asymmetry in (i) the height of the lateral offset regions and (ii) the lateral spatial extent of the lateral offset regions. In the example embodiment shown in FIGS. 2A-2C, the lateral extents of the lateral offset regions 122 and 124 are equal, as in the symmetric device shown in FIGS. 1A-1C, with the device asymmetric occurring due to the different heights (thicknesses) of the two lateral offset regions 122 and 124. Due to the asymmetric design, the electric field is stronger with the lateral offset region on the n+ side of the waveguide, compared to the electric field within the lateral offset region 122 on the p+ side, such that electrons subjected to a much larger field, with avalanche multiplication being dominated by electrons. In the example embodiment illustrated in FIGS. 3A-3C, the heights the lateral offset regions 122 and 124 are equal, as in the symmetric device shown in FIGS. 1A-1C, with the device asymmetric occurring due to the different lateral extents of the lateral offset regions 122 and 124. Due to the asymmetric design, the electric field extends over a longer lateral region within the lateral offset region 124 on the n+ side of the waveguide, compared to the lateral offset region 122 on the p+ side, such that electrons are subjected to an electric field over a longer interaction length, enabling avalanche multiplication to be dominated by electrons.

It will be understood, however, that asymmetry that favours electron avalanche multiplication and improved noise performance may be provided in two dimensions. For example, the asymmetry may be present in both the height and the lateral extent of the lateral offset regions 122 and 124, such that the height of the p+ side lateral offset region 122 is larger than the height of the n+ side lateral offset region 124, and such that the lateral extent of the n+ side lateral offset region 124 is larger than the lateral extent of the p+ side lateral offset region 122, with the n+ region 145 being further from the central waveguide region 130 than the p+ region 140. Such an example implementation may be beneficial in both enhancing the electric field and extending the spatial region over which impact ionization occurs, within the n+ side of the device where electron impact ionization occurs, thus leading to enhanced electron avalanche multiplication and supressed or eliminated hole avalanche multiplication. The reverse bias may be applied such that a threshold of avalanche multiplication is achieved for electrons without achieving a threshold of avalanche multiplication is achieved for holes.

It is to be understood that the ridge waveguide/SOI configuration shown in FIGS. 2A and 3A are provided as non-limiting examples, and that other configurations are possible, provided that the waveguide is doped with deep level impurities, includes at least one guided mode at a sub-bandgap wavelength. For example, in other embodiments, the central waveguide may be provided in the form of a rib waveguide, a buried waveguide, and air bridge waveguide.

While the preceding example embodiments have described waveguide avalanche photodetectors formed from a silicon device layer, in other example implementations, the semiconductor may be a semiconductor other than silicon, provided that a suitable deep level dopant is provided. Suitable examples of semiconductors and associated deep level dopants include, but are not limited to, germanium doped with sulfur or gallium arsenide doped with nickel, tin or cobalt.

In some example implementations, an avalanche photodiode device according to the previously described embodiments may be integrated in photonic systems which require an electrical response to the presence of light, whether as a terminal detector in a receiver system, a terminal detector at the end of a tap measuring a small portion of the light present in a waveguide or as an in-line tap detector.

Furthermore, avalanche photodiode devices according to the previously described embodiments may be incorporated into resonant structures, such as micro-ring resonators and Fabry-Perot cavities which may act to sensitize the avalanche photodetector in a spectrally-selective manner. Grating structures may be etched into the silicon to provide the reflections necessary to construct a resonant cavity but may also be implemented through patterned implantation of the defects themselves.

In other example implementations, an avalanche photodiode device according to the previously described embodiments may be implemented in photonic crystal slow-light structure or subwavelength grating structure that acts to reduce the group velocity of the incident light, which could substantially increase the signal present in the avalanche photodiode device.

Furthermore, while the preceding example embodiments have been described with reference to a waveguide configuration in which a central waveguide region, having deep levels, is employed for both guiding and absorption of the sub-bandgap light that is to be detected, the preceding example configurations may be adapted to provide lateral avalanche photodetector devices that need not necessarily confine the incident light as a guided optical mode during deep-level-mediated absorption and photocarrier generation. For example, the light may be incident at the surface of the device, while the avalanche and extraction of carriers may take place in the lateral dimension.

In other example implementations, the preceding example embodiments, which employed the presence of deep levels to facilitate absorption, may be modified, adapted or employed for operation via the absorption and detection of above-bandgap light, where avalanche multiplication of electrons predominates over avalanche multiplication of holes via the aforementioned asymmetry in one or both of height and lateral extent of the lateral offset regions. In such example implementations, deep levels may be optionally omitted, since optical absorption occurs across the semiconductor bandgap. In some example implementations, however, at least the n+ side lateral offset region may be doped with deep levels to facilitate an increased probability (cross-section) for impact ionization of electrons.

The specific embodiments described above have been shown by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

Therefore what is claimed is:

1. An asymmetric waveguide avalanche photodiode device comprising:
a substrate; and
a silicon device layer residing on said substrate, said silicon device layer comprising:
a silicon waveguide comprising deep levels;
an n-type region residing on a first side of said silicon waveguide;
a first silicon lateral offset region laterally extending between said silicon waveguide and said n-type region;
a p-type region residing on a second side of said silicon waveguide; and
a second silicon lateral offset region laterally extending between said silicon waveguide and said p-type region;
wherein a height of said second silicon lateral offset region exceeds a height of said first silicon lateral offset region, thereby establishing a spatial asymmetry that enhances avalanche multiplication, within said first silicon lateral offset region, of electrons photogenerated by absorption of sub-bandgap light by the deep levels, relative to avalanche multiplication of photogenerated holes, when a reverse bias, sufficient for generating impact ionization within said first silicon lateral offset region, is applied between said p-type region and said n-type region.

2. The device according to claim 1 wherein a lateral extent of said first silicon lateral offset region, along a direction perpendicular to a longitudinal axis of said silicon waveguide, exceeds a lateral extent of said second silicon lateral offset region.

3. The device according to claim 1 wherein the height of said second silicon lateral offset region is less than 0.99 times a height of said silicon waveguide.

4. The device according to claim 1 wherein the height of said first silicon lateral offset region is greater than 0.01 times a height of said silicon waveguide.

5. The device according to claim 1 wherein said second silicon lateral offset region has a lateral extent of at least 100 nm.

6. The device according to claim 1 wherein said second silicon lateral offset region has a lateral extent such that parasitic absorption of light guided by said silicon waveguide and having a wavelength of 1500 nm is less than 10%.

7. The device according to claim 1 wherein a concentration of deep levels in said silicon waveguide is at least 10¹⁴ cm⁻³.

8. The device according to claim 1 wherein said first silicon lateral offset region comprises deep levels.

9. The device according to claim 8 wherein a concentration of deep levels in said first silicon lateral offset region is greater than a concentration of deep levels in said second silicon lateral offset region.

10. The device according to claim 1 wherein a concentration of shallow dopants in said silicon waveguide is less than 10¹⁹ cm⁻³.

11. An asymmetric avalanche photodiode device comprising:
a substrate; and
a semiconductor device layer residing on said substrate, said semiconductor device layer comprising:
an elongate semiconductor region suitable for absorbing incident light and responsively generating photocarriers;
an n-type region residing on a first side of said elongate semiconductor region;
a first semiconductor lateral offset region laterally extending, in a direction perpendicular to a longitudinal axis of said elongate semiconductor region, between said elongate semiconductor region and said n-type region;
a p-type region residing on a second side of said elongate semiconductor region; and
a second semiconductor lateral offset region laterally extending between said elongate semiconductor region and said p-type region;
wherein a height of said second semiconductor lateral offset region exceeds a height of said first semiconductor lateral offset region, thereby establishing a spatial asymmetry that enhances avalanche multiplication, within said first semiconductor lateral offset region, of electrons photogenerated by absorption of light within said elongate semiconductor region, relative to avalanche multiplication of photogenerated holes, when a reverse bias, sufficient for generating impact ionization within said first semiconductor lateral offset region, is applied between said p-type region and said n-type region.

12. An asymmetric waveguide avalanche photodiode device comprising:
a substrate; and
a silicon device layer residing on said substrate, said silicon device layer comprising:
a silicon waveguide comprising deep levels;
an n-type region residing on a first side of said silicon waveguide;
a first silicon lateral offset region laterally extending between said silicon waveguide and said n-type region;
a p-type region residing on a second side of said silicon waveguide; and
said first silicon lateral offset region having a lateral extent, along a direction perpendicular to a longitudinal axis of said silicon waveguide, such that said n-type region resides further from said silicon waveguide than said p-type region, thereby establishing a spatial asymmetry that enhances avalanche multiplication, within said first silicon lateral offset region, of electrons photogenerated by absorption of sub-bandgap light by the deep levels, relative to avalanche multiplication of photogenerated holes, when a reverse bias, sufficient for generating impact ionization within said first silicon lateral offset region, is applied between said p-type region and said n-type region.

13. The device according to claim 12 wherein said p-type region is laterally offset from said silicon waveguide by a second silicon lateral offset region, and wherein the lateral extent of said first silicon lateral offset region exceeds a lateral extent of said second silicon lateral offset region.

14. The device according to claim 13 wherein said first silicon lateral offset region is absent of a p-doped subregion.

15. The device according to claim 14 wherein a maximum electric field within said second silicon lateral offset region exceeds a maximum electric field within said first silicon lateral offset region under application of the reverse bias.

16. The device according to claim 12 wherein a concentration of deep levels in said silicon waveguide is at least 10¹⁴ cm⁻³.

17. The device according to claim 12 wherein said first silicon lateral offset region comprises deep levels.

18. The device according to claim 12 wherein a concentration of shallow dopants in said silicon waveguide is less than 10¹⁹ cm⁻³.

19. An asymmetric avalanche photodiode device comprising:
a substrate; and
a semiconductor device layer residing on said substrate, said semiconductor device layer comprising:
an elongate semiconductor region suitable for absorbing incident light and responsively generating photocarriers;
an n-type region residing on a first side of said elongate semiconductor region;
a first semiconductor lateral offset region laterally extending between said elongate semiconductor region and said n-type region;
a p-type region residing on a second side of said elongate semiconductor region; and
a second semiconductor lateral offset region laterally extending between said elongate semiconductor region and said p-type region;
said first semiconductor lateral offset region having a lateral extent, along a direction perpendicular to a longitudinal axis of said elongate semiconductor region, such that said n-type region resides further from elongate semiconductor region than said p-type region, thereby establishing a spatial asymmetry that enhances avalanche multiplication, within said first semiconductor lateral offset region, of electrons photogenerated by absorption of light within said elongate semiconductor region, relative to avalanche multiplication of photogenerated holes, when a reverse bias, sufficient for generating impact ionization within said first semiconductor lateral offset region, is applied between said p-type region and said n-type region.
